(19) United States
(12) Patent Application Publication
(10) Pub. No.: US 2025/0070722 A1
(43) Pub. Date: Feb. 27, 2025

(54) SUPPLY MODULATOR AND WIRELESS COMMUNICATION DEVICE INCLUDING THE SAME

(71) Applicant: Samsung Electronics Co., Ltd., Suwon-si (KR)

(72) Inventors: Ikhwan KIM, Suwon-si (KR); Junsuk BANG, Suwon-si (KR); Jeongil SEO, Suwon-si (KR)

(73) Assignee: Samsung Electronics Co., Ltd., Suwon-si (KR)

(21) Appl. No.: 18/741,079

(22) Filed: Jun. 12, 2024

(30) Foreign Application Priority Data
Aug. 22, 2023 (KR) 10-2023-0109925
Oct. 17, 2023 (KR) 10-2023-0138978

(51) Int. Cl. H03F 1/02; H03F 3/24; H04B 1/04

(52) U.S. Cl. CPC H03F 1/0233; H03F 3/245; H04B 1/04; H03F 2200/451

(57) ABSTRACT

A power modulator configured to provide a supply voltage of a power amplifier. The power modulator includes a converter configured to output the supply voltage to the power amplifier, a switch connected to a first capacitor and a second capacitor, a first end of the first capacitor being connected to the converter, a second end of the first capacitor being connected to the switch, a first end of the second capacitor being connected to the converter, a second end of the second capacity being connected to a ground and the switch, and a capacitance of the second capacitor being less than a capacitance of the first capacitor, and a driver connected to the switch, the driver being configured to turn off the switch based on an occurrence of a transition of the supply voltage.

### CROSS-REFERENCE TO RELATED APPLICATION(S)

This U.S. non-provisional application claims priority under 35 USC § 119 to Korean Patent Application No. 10-2023-0109925, filed on Aug. 22, 2023 and Korean Patent Application No. 10-2023-0138978, filed on Oct. 17, 2023, in the Korean Intellectual Property Office, the disclosures of each of which are herein incorporated by reference in their entireties.

### BACKGROUND

Example embodiments relate to a supply modulator and a wireless communication device including the same.

In wireless communication devices such as smartphones, tablets, and Internet of Things (IoT) devices, wideband code-division multiple access (WCDMA) (3G), long term evolution (LTE), LTE advanced (4G), or new radio (NR) (5G) technology is used for high-speed communication. These apparatuses may receive power from a power amplifier supplied by a power supply. However, the efficiency of the power amplifier decreases when a higher peak-to-average power ratio (PAPR) and a higher bandwidth for communicating signals is used. When the power supply of the power amplifier of a transmission end is connected to a battery, the decrease in efficiency of the power amplifier is noticeable (and/or significant). Accordingly, average power tracking (APT) or envelope tracking (ET) is used to improve the power efficiency of the power amplifier at a higher PAPR and a higher bandwidth. A chip or a component supporting APT and ET is referred to as a supply modulator (SM).

However, average power tracking for an existing power modulator may not be effectively applied to a symbol unit smaller than a slot unit because transition time of a supply voltage is optimized (or configured) for the slot unit.

### SUMMARY

Example embodiments provide a supply modulator and a wireless communication device including the same.

According to example embodiments, a power modulator configured to provide a supply voltage of a power amplifier, the power modulator including a converter configured to output the supply voltage to the power amplifier, a switch connected to a first capacitor and a second capacitor, a first end of the first capacitor being connected to the converter, a second end of the first capacitor being connected to the switch, a first end of the second capacitor being connected to the converter, a second end of the second capacity being connected to a ground and the switch, and a capacitance of the second capacitor being less than a capacitance of the first capacitor, and a driver connected to the switch, the driver being configured to turn off the switch based on an occurrence of a transition of the supply voltage.

According to example embodiments, a wireless communication device includes a power amplifier configured to amplify a radio-frequency (RF) signal, a power modulator configured to provide a supply voltage of the power amplifier, a first capacitor connected to the power amplifier and the power modulator, and, a second capacitor connected to the power amplifier and the power modulator, wherein the power modulator includes a converter configured to output the supply voltage to the power amplifier, a switch connected to the first capacitor and the second capacitor, a first end of the first capacitor being connected to the converter, a second end of the first capacitor being connected to the switch, a first end of the second capacity being connected to the converter, a second end of the second capacitor being connected to a ground and the switch, and a capacitance of the second capacitor being less than a capacitance of the first capacitor, and a driver connected to the switch, and the driver being configured to turn off the switch based on an occurrence of a transition of the supply voltage.

According to example embodiments, a power modulator configured to provide a supply voltage of a power amplifier, the power modulator including a converter configured to output the supply voltage to the power amplifier, a switch connected to a first capacitor and a second capacitor, a first end of the first capacity being connected to the converter, a second end of the first capacitor being connected to the switch, a first end of the second capacitor being connected to the converter, a second end of the second capacitor being connected to a ground and the switch, and a capacitance of the second capacitor being less than a capacitance of the first capacitor, and a driver connected to a gate terminal of the switch, the driver being configured to apply a lower voltage among a first voltage or a ground voltage to the gate terminal of the switch based on an occurrence of a transition of the supply voltage, the first voltage being a voltage at the second end of the first capacitor, and the ground voltage being a voltage at the ground.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a diagram illustrating a wireless communication device according to example embodiments.

FIG. 2 is a diagram illustrating a signal processing process of a digital processing circuit according to example embodiments.

FIG. 3 is a diagram illustrating a power modulator according to example embodiments.

FIG. 4 is a diagram illustrating a power modulator according to example embodiments.

FIG. 5 is a diagram illustrating a rising transition operation of a power modulator according to example embodiments.

FIG. 6 is a diagram illustrating a falling transition operation of a power modulator according to example embodiments.

FIG. 7 is a diagram illustrating a comparison between a supply voltage of a power modulation scheme of a power modulator according to example embodiments and a supply voltage of an example power modulation scheme.

FIG. 8 is a diagram illustrating a comparison between a supply voltage of a power modulation scheme of a power modulator according to example embodiments and a supply voltage of an example power modulation scheme, for symbols.

FIG. 9 is a diagram illustrating a power modulator according to example embodiments.

FIG. 10 is a diagram illustrating a power modulator according to the example of FIG. 9.

FIG. 11 is a diagram illustrating an operating waveform of a power modulator according to example embodiments.

FIG. 12 is a diagram illustrating a power modulator including a protection circuit according to example embodiments.

FIG. 13 is a circuit diagram of the protection circuit of FIG. 12 according to example embodiments.

FIG. 14 is a diagram illustrating an Internet of Things (IoT) device to which a wireless communication device according to example embodiments is applied.

FIG. 15 is a diagram illustrating a mobile terminal to which a wireless communication device according to example embodiments is applied.

### DETAILED DESCRIPTION

Hereinafter, example embodiments will be described with reference to the accompanying drawings.

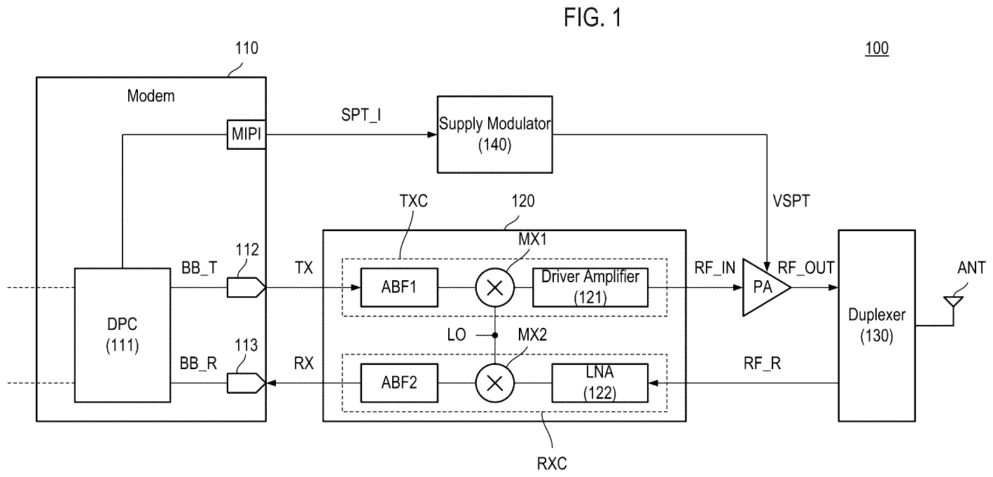

FIG. 1 is a diagram illustrating a wireless communication device according to example embodiments.

Referring to FIG. 1, a wireless communication device 100 may include a modem 110, a radio-frequency integrated circuit (RFIC) 120, a power amplifier PA, a duplexer 130, a power modulator 140, and/or an antenna ANT.

The modem 110 may include a digital processing circuit 111, a digital-to-analog converter (DAC) 112, an analog-to-digital converter (ADC) 113, and/or a mobile industry processor interface (MIPI). The modem 110 may process a baseband signal BB_T (for example, including an I signal and a Q signal) including information to be transmitted through the digital processing circuit 111, according to various communication methods.

The modem 100 may process the received baseband signal BB_R through the digital processing circuit 111 according to various communication methods.

For example, the modem 110 may process a signal to be transmitted or a received signal, according to a communication method such as orthogonal frequency division multiplexing (OFDM), orthogonal frequency division multiple access (OFDMA), wideband code division multiple access (WCDMA), or high speed packet access (HSPA+). In addition, the modem 110 may process the baseband signal BB_T or the baseband signal BB_R according to various communication methods (for example, various communication methods to which a technique for modulating or demodulating an amplitude and/or a frequency of the baseband signal BB_T or BB_R is applied).

The modem 110 may generate an average power signal based on an average power tracking (APT) table stored in a memory. The APT table stores information on a required (or corresponding) supply voltage of a power amplifier PA for the expected output power (or transmit power) of the antenna ANT, and may store information on an average power signal corresponding to the required (or corresponding) supply voltage of the power amplifier PA. Therefore, when the expected output power of the antenna ANT is determined, the modem 110 may generate an average power signal using the APT table and provide symbol power tracking (SPT) information SPT_I, including the generated average power signal, to the power modulator 140. In this case, the SPT information SPT_I may include the average power signal, symbol information to be tracked, or the like.

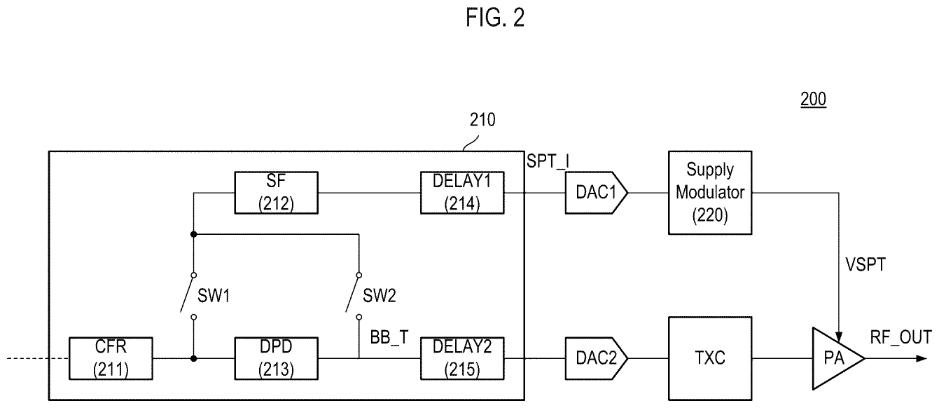

The digital processing circuit 111 may perform various processing operations on baseband signals in a digital domain, and more detailed operations will be described later with reference to FIG. 2.

Each of the DAC 112 and the ADC 113 may be provided with at least one signal. The modem 110 may perform digital-to-analog conversion on the baseband signal BB_T using the DAC 112 to generate a transmit signal TX. The modem 110 may receive a receive signal RX, an analog signal, from the RFIC 120. The modem 110 may digitally convert the receive signal RX through the ADC 113, provided therein, to extract the baseband signal BB_R, a digital signal. For example, the receive signal RX may be a differential signal including a positive signal and a negative signal.

The RFIC 120 may perform frequency up-conversion on the transmit signal TX to generate an RF input signal RF_IN, or may perform frequency down-conversion on the RF receive signal RF_R to generate a receive signal RX. For example, the RFIC 120 may include a transmit circuit TXC for frequency up-conversion, a receive circuit RXC for frequency down-conversion, and/or a local oscillator LO.

The transmit circuit TXC may include a first analog baseband filter ABF1, a first mixer MX1, and/or a driver amplifier 121. For example, the first analog baseband filter ABF1 may include a low-pass filter.

The baseband filter ABF1 may filter the transmit signal TX, received from the modem 110, and provide the filtered signal to the first mixer MX1. The first mixer MX1 may perform frequency up-conversion to convert a frequency of the transmit signal TX from a baseband into a higher-frequency band through a frequency signal applied by the local oscillator LO. Through the frequency up-conversion, the transmit signal TX may be provided to a driver amplifier 121 as an RF input signal RF_IN, and the driver amplifier 121 may firstly amplify power of the RF input signal RF_IN and may provide apply the power-amplified RF input signal RF_IN to the power amplifier PA.

The power amplifier PA may receive a DC voltage or a variable power supply voltage (for example, a dynamically variable output voltage), and may secondly amplify the power of the RF input signal RF_IN to generate an RF output signal RF_OUT. The power amplifier PA may provide the generated RF output signal RF_OUT to the duplexer 130.

The receive circuit RXC may include a second analog baseband filter ABF2, a second mixer MX2, and/or a low-noise amplifier (LNA) 122. For example, the second analog baseband filter ABF2 may include a low-pass filter.

The LNA 122 may amplify the RF receive signal RF_R received from the duplexer 130, and may provide the amplified RF receive signal RF_R to the second mixer MX2. The second mixer MX2 may perform frequency down-conversion to convert a frequency of the RF receive signal RF_R from a higher-frequency baseband into a baseband through a frequency signal applied by the local oscillator LO. Through the frequency down-conversion, the RF receive signal RF_R may be provided to the second analog baseband filter ABF2 as the receive signal RX. The second analog baseband filter ABF2 may filter the receive signal RX and may provide the filtered receive signal RX to the modem 100.

For reference, the wireless communication device 100 may transmit a transmit signal through a plurality of frequency bands using carrier aggregation (CA). To this end, the wireless communication device may also include a plurality of power amplifiers amplifying power of a plurality of RF input signals, respectively corresponding to a plurality of carrier waves. For clarity of description, examples will be provided herein in which there is only one power amplifier PA.

The duplexer 130 may be connected to the antenna ANT to separate a transmission frequency and a receiving frequency from each other. For example, the duplexer 130 may separate an RF output signal RF_OUT, received from the power amplifier PA, for each frequency band and may provide the separated RF output signal RF_OUT to a corresponding antenna ANT. Also, the duplexer 130 may provide an external signal, received from the antenna ANT, to the LNA 122 included in the receive circuit RXC of the RFIC 120. For example, the duplexer 130 may include a front end module with integrated duplexer (FEMiD).

For reference, the wireless communication device 100 may be provided with a switch structure, which may separate the transmission frequency and the receiving frequency, instead of the duplexer 130. Additionally, the wireless communication device 100 may be provided with a structure including a duplexer 130 and a switch to separate the transmission frequency and the receiving frequency. For clarity of description, examples will be provided herein in which the wireless communication device 100 includes a duplexer 130 may separate the transmission frequency and the receiving frequency.

The power modulator 140 may generate a modulated output voltage having an output voltage dynamically varied based on the average power signal, and may provide the output voltage as a supply voltage VSPT of the power amplifier PA.

For example, the power modulator 140 may receive SPT information SPT_I, including the average power signal, from the modem 110. The power modulator 140 may generate the dynamically variable supply voltage VSPT based on the received SPT information SPT_I. In addition, the power modulator 140 may provide the generated supply voltage VSPT to the power amplifier PA.

For reference, when a power supply voltage having a fixed level is applied to the power amplifier PA, power efficiency of the power amplifier PA may be deteriorated. Therefore, to efficiency manage power of the power amplifier PA, the power modulator 140 may modulate an input voltage (for example, power supplied from a battery) based on the SPT information SPT_I and may provide the modulated voltage to the power amplifier PA as a power supply voltage.

According to example embodiments, the power modulator 140 may include a switch provided therein to have a faster transition time of the supply voltage VSPT. For example, the transition time may be at a level at which power modulation is applicable to a duration unit of a single symbol included in the RF output signal RF_OUT. Accordingly, the power modulator 140 may provide the supply voltage VSP to the power amplifier PA after transitioning the supply voltage VSPT for each symbol duration.

In this case, the power amplifier PA may output an RF output signal RF_OUT having a modulated voltage for each of the plurality of symbols included in the RF output signal RF_OUT.

The antenna ANT may transmit an RF output signal RF_OUT, frequency-separated by the duplexer 130, to an external entity (e.g., another wireless communication device 100, a base station, an access point, etc.) or provide an RF receive signal RF_R, received from an external entity, to the duplexer 130. For example, the antenna ANT may include, but is not limited to, an array antenna.

For reference, the modem 110, the RFIC 120, the power amplifier PA, the duplexer 130, and/or the power modulator 140 may each be individually implemented as an integrated circuit (IC), a chip, or a module. Also, the modem 110, the RFIC 120, the power amplifier PA, the duplexer 130, and/or the power modulator 140 may be mounted together on a printed circuit board (PCB). However, example embodiments are not limited thereto. In example embodiments, at least a portion of the modem 110, the RFIC 120, the power amplifier PA, the duplexer 130, and/or the power modulator 140 may be implemented as a single communication chip.

Furthermore, the wireless communication device 100 of FIG. 1 may be included in a wireless communication system using a cellular network such as 5G or Long-Term Evolution (LTE), or may be included in a wireless local area network (WLAN) system or any other wireless communication systems. For reference, the structure of the wireless communication device 100 of FIG. 1 is merely an example and example embodiments are not limited thereto. For example, the wireless communication device 100 may be configured in various ways based on a communication protocol or a communication method.

FIG. 2 is a diagram illustrating a signal processing process of a digital processing circuit according to example embodiments.

Referring to FIG. 2, the digital processing circuit 111 may perform, for example, the above-described average power signal generation operation, an envelope extraction operation when envelope tracking operation is supported, a digital envelope signal generation operation, a crest factor reduction (CFR) 211, a shaping function (SF) 212, digital pre-distortion (DPD) 213, delay correction operations 214 and/or 215), or the like. Also, the digital processing circuit 111 may include a switch SW1, connected to an input terminal of the SF 212 and an output terminal of the CFR 211, and a switch SW2 connected to an input terminal of the SF 212 and an output terminal of the DPD 213. The wireless communication device 200, the modem 210, the supply modulator 220, the power amplifier PA, the transmit circuit TXC, and/or the DAC2 may be the same as or similar to the wireless communication device 100, the modem 110, the supply modulator 140, the power amplifier PA, the transmit circuit TXC, and/or the DAC 112 discussed in connection with FIG. 1, respectively.

The CFR 211 may reduce a peak-to-average power ratio (PAPR) of a communication signal (for example, a baseband signal BB_T). The SF 212 may transform a digital envelope signal to improve efficiency and linearity of the power amplifier PA. The DPD 213 may compensate for and linearize distortion of the power amplifier PA in a digital domain. The delay correction operations 214 and 215 may be performed to correct a delay of the digital envelope signal or the baseband signal BB_T.

The SPT information SPT_I may be converted into an analog signal through DAC1 and provided to the power modulator 220. The power modulator 220 may modulate and provide a supply voltage VSPT to the power amplifier PA, and the power amplifier PA may output an RF output signal RF_OUT. The baseband signal BB_T may be converted into a transmit signal through DAC2, and then provided to the transmit circuit TXC.

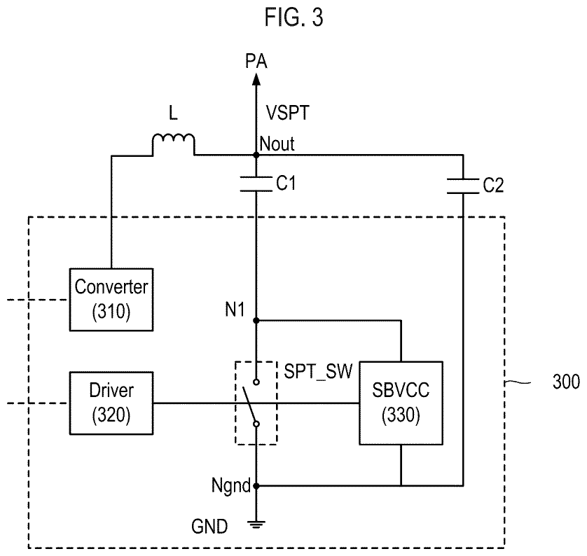

FIG. 3 is a diagram illustrating a power modulator according to example embodiments.

Referring to FIG. 3, the power modulator 300 may be connected to a power amplifier PA and configured to provide a supply voltage VSPT of the power amplifier PA. The power modulator 300 according to example embodiments may adjust and provide the supply voltage VSPT in units of symbol durations of an RF signal. To adjust and provide the supply voltage VSPT in units of symbol durations, the power modulator 300 may be configured to provide the supply voltage VSPT with a transition time significantly lower than a time corresponding to a single symbol duration when the supply voltage VSPT transitions.

The power modulator 300 according to example embodiments may include a converter 310, a switch SPT_SW, and/or a driver 320 to adjust and provide a supply voltage VSPT in units of symbol durations.

The converter 310 may be configured to generate and/or adjust a supply voltage VSPT and output the supply voltage VSPT to the power amplifier PA. The converter 310 may operate based on a driving voltage (for example, a battery voltage). The converter 310 may receive a control signal from the above-described modem 110 of FIG. 1, and may generate and/or adjust the supply voltage VSPT to be provided to the power amplifier PA from the driving voltage based on the control signal. According to various examples, the converter 310 may be implemented as a boost converter, a buck converter, or a buck-boost converter.

An inductor L, storing energy and providing the supply voltage VSPT in the form of current to the power amplifier PA, may be connected to an output terminal of the converter 310. The inductor L may have one end, connected to the output terminal of the converter 310, and the other end connected to an output node Nout connected to the power amplifier PA. A first capacitor C1 and a second capacitor C2 may be connected to the converter 310 through the output node Nout. Hereinafter, it will be understood that when an element is referred to as being “connected” or “coupled” to another element, it may be directly connected or coupled to the other element or intervening elements may be present. In contrast, when an element is referred to as being “directly connected” or “directed coupled” to another element, there are no intervening elements. In addition, one end and the other end of a capacitor may be understood as either a top plate or a bottom plate of the capacitor.

According to example embodiments, the inductor L, the first capacitor C1, and the second capacitor C2 may be provided between the power modulators 140 and 220 illustrated in FIGS. 1 and 2, or the power modulator 300 illustrated in FIG. 3 and the power amplifier PA.

The first capacitor C1 may have one end, connected to the output node Nout, and the other end connected to a switch SPT_SW and a switch body voltage control circuit 330 through the first node N1. The second capacitor C2 may be connected to a ground node Ngnd having one end, connected to the output node Nout, and the other end connected to a ground GND. According to example embodiments, the second capacitor C2 may have capacitance less than capacitance of the first capacitor C1. Therefore, as will be described later, a transition of the supply voltage VSPT may be faster when only the second capacitor C2 is connected to the output node Nout than when both the first capacitor C2 and the second capacitor C2 are connected to the output node Nout.

The switch SPT_SW may be connected to the other terminal of the first capacitor C1 and the other terminal of the second capacitor C2. For example, one end of the switch SPT_SW may be connected to the other end of the first capacitor C1 through a first node N1, and the other end of the switch SPT_SW may be connected to a ground node Ngnd, the other end of the second capacitor C2. The switch SPT_SW may be turned on or turned off under the control of the driver 320.

According to example embodiments, when the power modulator 300 operates in a normal state, the switch SPT_SW may be turned on under the control of the driver 320. As the switch SPT_SW is turned on, both the first capacitor C1 and the second capacitor C2 may be connected to the output node Nout. For example, the other end of the first capacitor C1 may be connected to the ground node Ngnd depending on the turn-on of the switch SPT_SW. Accordingly, as the total capacitance connected to the output node Nout is relatively increased, the supply voltage VSPT may be stably supplied to the power amplifier PA.

According to example embodiments, when a transition of the supply voltage VSPT occurs, the switch SPT_SW may be turned off under the control of the driver 320. The other end of the first capacitor C1, for example, one end of the switch SPT_SW, may float based on the switch SPT_SW being turned off. Ultimately, only the second capacitor C2 may be connected to the output node Nout. Accordingly, the transition of the supply voltage VSPT may be performed more rapidly as the total capacitance of the second capacitor C2 connected to the output node Nout is relatively reduced when the switch SPT_SW is turned off. The converter 310 may adjust the supply voltage VSPT through the second capacitor C2 based on the switch SPT_SW being turned off.

The driver 320 may be connected to the switch SPT_SW and configured to turn off the switch SPT_SW based on occurrence of a transition of the supply voltage VSPT. According to example embodiments, when the switch SPT_SW is implemented as a transistor, the driver 320 may control the switch SPT_SW based on adjustment of the gate voltage of the switch SPT_SW. The driver 320 may operate under the control of the above-described modem 110 of FIG. 1. For example, the driver 320 may turn on the switch SPT_SW in a normal state, and may turn off the switch SPT_SW when a transition of the supply voltage VSPT occurs. According to example embodiments, as discussed above in connection with FIG. 1, the power amplifier PA may amplify the power of an RF input signal RF_IN to generate an RF output signal RF_OUT based on the supply voltage VSPT, and the antenna ANT may transmit the RF output signal RF_OUT to an external entity (e.g., another wireless communication device 100, a base station, an access point, etc.).

According to example embodiments, the power modulator 300 may further include a switch body voltage control circuit 330 connected to the switch SPT_SW. According to example embodiments, when the switch SPT_SW is implemented as a transistor, the switch body voltage control circuit 330 may control a body voltage of the switch SPT_SW to prevent current from flowing (or reduce the amount of current flowing) from the switch SPT_SW to the first node N1. Accordingly, the switch body voltage control circuit 330 may allow the switch SPT_SW to be completely turned off.

The switch body voltage control circuit 330 may control the body voltage of the switch SPT_SW depending on whether the transition of the supply voltage VSPT is a rising transition or a falling transition. In example embodiments, a rising transition may refer to an increase in the magnitude of the supply voltage VSPT, and a falling transition may refer to a decrease in the magnitude of the supply voltage VSPT.

According to example embodiments, the switch body voltage control circuit 330 may adjust the body voltage of the switch SPT_SW to the lower of a voltage at the other end of the first capacitor C1 (for example, a first node voltage) or a voltage of the ground GND (for example, a ground voltage). For example, when the supply voltage VSPT rises, the first node voltage may be a positive voltage. Accordingly, the switch body voltage control circuit 330 may adjust the body voltage of the switch SPT_SW to the ground voltage lower than the first node voltage. Alternatively, for example, when the supply voltage VSPT falls, the first node voltage may be a negative voltage. Accordingly, the switch body voltage control circuit 330 may adjust the body voltage of the switch SPT_SW to the first node voltage. According to the above-described examples, there is no case in which the body voltage of the switch SPT_SW is higher than the first node voltage, regardless of whether the transition is a rising or falling transition. Accordingly, the switch SPT_SW may be completely turned off through the switch body voltage control circuit 330.

According to the above-described examples, the power modulator 300 may reduce a transition time of the supply voltage VSPT through a switch SPT_SW that may float a larger capacitor when the switch SPT_SW is turned off. This allows the modulation of the supply voltage VSPT to be applied in units of symbol durations. When the transition time is longer, voltage modulation should be performed prior to several symbols to modulate the voltage of a specific symbol duration, causing unnecessary (or excessive) power consumption and noise, and deteriorating error vector magnitude (EVM) characteristics. To reduce the transition time, increasing current at an output terminal or reducing a load capacitor may be taken into account. However, increasing current may lead to increased power consumption of the converter 310, heat generation caused by power loss, saturation current of the inductor L, or the like. In addition, reducing the load capacitor may lead to an increase in voltage ripple at the output terminal and difficulty in stably supplying a voltage. According to example embodiments, the voltage transition time may be reduced to apply voltage modulation in units of symbol durations without reducing the load capacitor or increasing the current, through the floating of the capacitor. As a result, unnecessary (or excessive) power consumption and noise may be reduced, and EVM characteristics may be improved.

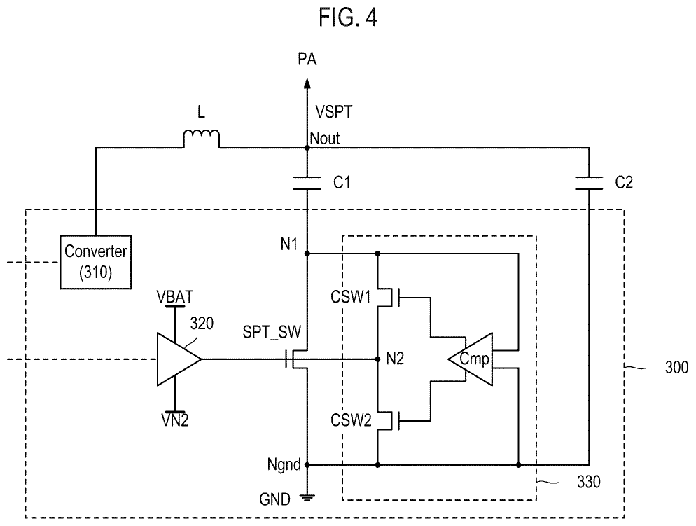

FIG. 4 is a diagram illustrating a power modulator according to example embodiments.

Referring to FIG. 4, a driver 320 included in a power modulator 300 according to example embodiments may operate based on a driving voltage VBAT and a voltage at a second node N2 connected to a body of a switch SPT_SW. An output terminal of the driver 320 may be connected to a gate terminal of the switch SPT_SW to apply the driving voltage VBAT or the second node voltage VN2 to a gate terminal of the switch SPT_SW.

In a normal state, the driver 320 may apply the driving voltage VBAT to the gate terminal of the switch SPT_SW. Accordingly, the switch SPT_SW may be turned on in a normal state to connect a first capacitor C1 to a ground GND. Both the first capacitor C1 and a second capacitor C2 may be connected to an output node Nout, allowing a converter 310 connected to the inductor L to provide a supply voltage VSPT to a power amplifier PA according to the first capacitor C1 and the second capacitor C2.

When a transition of the supply voltage VSPT occurs, the driver 320 may apply the second node voltage VN2 to the gate terminal of the switch SPT_SW. Accordingly, the switch SPT_SW may be turned off to float the first capacitor C1. Only the second capacitor C2 may be connected to the output node Nout (when the switch SPT-SW is turned off), so that the converter 310 may provide the power amplifier PA with a supply voltage VSPT transitioning more rapidly depending on the second capacitor C2.

The second node voltage VN2, applied to the gate terminal of the switch SPT_SW through the driver 320, may be controlled by the switch body voltage control circuit 330. According to example embodiments, the switch body voltage control circuit 330 may include a first control switch CSW1, a second control switch CSW2, and/or a comparator Cmp.

The first control switch CSW1 may have one end, connected to the other end of the first capacitor C1 (for example, a first node N1), and the other end connected to a body of the switch SPT_SW (for example, a second node N2). The gate terminal of the first control switch CSW1 may be connected to an output terminal of the comparator Cmp, and thus the first control switch CSW1 may be turned on or off depending on the comparator Cmp.

The second control switch CSW2 may have one end, connected to the ground GND (for example, a ground node Ngnd), and the other end connected to the body (for example, the second node N2 of the switch SPT_SW). Similarly, the gate terminal of the second control switch CSW2 may be connected to the output terminal of the comparator Cmp, and thus the second control switch CSW2 may be turned on or off depending on the comparator Cmp.

For example, one end of the switch SPT_SW and one end of the first control switch CSW1 may be connected to the first node N1, the body of the switch SPT_SW, the other end of the first control switch CSW1, and the other end of the second control switch CSW2 may be connected to the second node N2, and the other end of the switch SPT_SW and one end of the second control switch CSW2 may be connected to the ground node Ngnd.

The comparator Cmp may have an input terminal(s), to which the first node N1 and the ground node Ngnd are connected, and an output terminal to which the first control switch CSW1 and a second control switch CSW2 connected. The comparator Cmp may be configured to compare the first node voltage and the ground voltage, and to control the first control switch CSW1 and the second control switch CSW2 based on a result of the comparison.

According to example embodiments, the comparator Cmp may turn off the first control switch CSW1 and turn on the second control switch CSW2 based on the first node voltage being higher than the ground voltage. Accordingly, the second node voltage VN2 may be adjusted to the ground voltage, a voltage at the ground node Ngnd connected to the second control switch CSW2.

Alternatively, the comparator Cmp may turn on the first control switch CSW1 and turn off the second control switch CSW2 based on the first node voltage being lower than the ground voltage. Accordingly, the second node voltage VN2 may be adjusted to the first node voltage, a voltage at the first node N1 connected to the first control switch CSW1. Therefore, according to the above-described examples, the comparator Cmp may adjust the second node voltage VN2 to the lower of the first node voltage and the ground voltage.

When a rising transition of the supply voltage VSPT occurs, the first node voltage becomes higher than the ground voltage, and thus the comparator Cmp may turn on the second control switch CSW2 during the rising transition to adjust the second node voltage VN2 to the ground voltage. Alternatively, when a falling transition of the supply voltage VSPT occurs, the first node voltage becomes lower than the ground voltage, and thus the comparator Cmp may turn on the first control switch CSW1 during the falling transition to adjust the second node voltage VN2 to the first node voltage.

The driver 320 may apply the second node voltage VN2 to the gate terminal of the switch SPT_SW when the switch SPT_SW is to be turned off. Accordingly, the driver 320 may apply the ground voltage to the gate voltage of the switch SPT_SW based on the rising transition of the supply voltage VSPT. Alternatively, the driver 320 may apply the first node voltage to the gate voltage of the switch SPT_SW based on the falling transition of the supply voltage VSPT. In any case, when the supply voltage VSPT transitions, the driver 320 may prevent current from flowing (or reduce an amount of the current flowing) from the switch SPT_SW node to the first node N1 and may completely turn off the switch SPT_SW.

According to the above-described examples, the power modulator may adjust the body voltage of the switch SPT_SW to the lower of the voltages at opposite ends of the switch SPT_SW through the switch body voltage control circuit 330. Accordingly, when the switch SPT_SW is turned off, the second node voltage VN2 applied to the gate terminal of the switch SPT_SW through the driver 320 may be prevented from being higher than the first node voltage (or an occurrence thereof may be reduced), so that the switch SPT_SW may be turned off more stably. For example, even when a negative voltage is generated among the voltages at the opposite ends of the switch SPT_SW, the switch body voltage control circuit 330 may adjust a lower negative voltage to the body voltage of the switch SPT_SW, so that the switch body voltage control circuit 330 may adjust a lower negative voltage to the body voltage of the switch SPT_SW. As a result, turn-off of the switch SPT_SW may be stably performed even when one end of the switch SPT_SW is at a negative voltage.

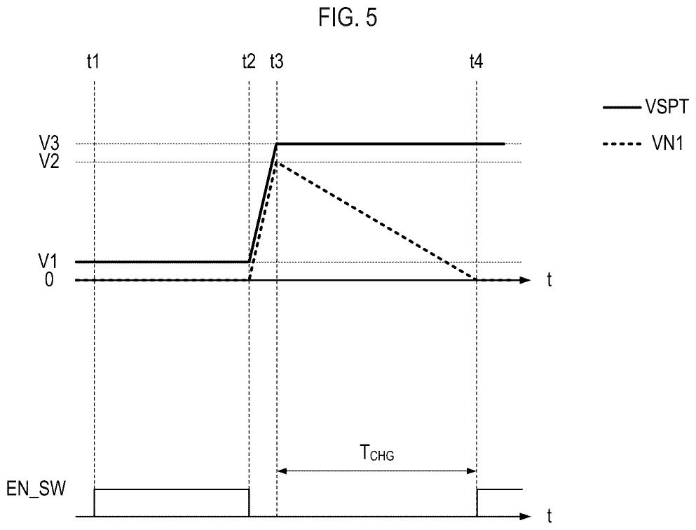

FIG. 5 is a diagram illustrating a rising transition operation of a power modulator according to example embodiments.

Referring to FIG. 5, the supply voltage VSPT and the first node voltage VN1 may vary depending on whether an enable signal EN_SW, indicating that the switch SPT_SW of FIGS. 3 and 4 has been turned on, is logic high or low. At time t1, when the enable signal EN_SW is logic high, the switch SPT_SW may be maintained in a turned-on state and the first capacitor C1 may be connected to the ground node Ngnd. Accordingly, the first node voltage VN1 may represent the ground voltage, and the supply voltage VSPT may represent a level V1 before the transition. For example, in a normal state, there may be a difference of V1 between the supply voltage VSPT and the first node voltage VN1.

At time t2, when the enable signal EN_SW is converted into a low-level signal, the switch SPT_SW may be turned off and the first capacitor C1 may float. From time t2, the supply voltage VSPT may rise, and the first node voltage VN1 may also rise with the same slope as (or a similar slop to) the supply voltage VSPT. In this case, the first node voltage VN1 may rise while maintaining a difference of V1 from the supply voltage VSPT.

After time t3, the supply voltage VSPT may complete a rising transition to a level V3, and the first node voltage VN1 may complete a rising transition to a level V2 that is V1 lower than V3. When the rising transition is completed at time t3, the first node voltage VN1 may be discharged to a ground voltage until time t4. Then, the enable signal EN_SW may be switched back to the high level, and the first capacitor C1 may be reconnected to the ground GND. The first capacitor C1 may be discharged during T_{CHG} defined as time from time t3 to time t4.

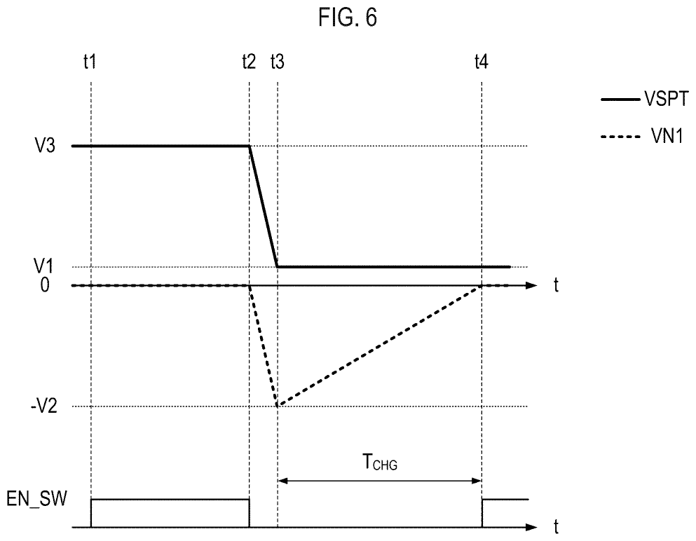

FIG. 6 is a diagram illustrating a falling transition operation of a power modulator according to example embodiments.

Referring to FIG. 6, when the supply voltage VSPT represents V3 and the first node voltage VN1 represents the ground voltage through the rising transition of FIG. 5, a falling transition may start. From time t1 to time t2, the enable signal EN_SW may be maintained in a logic-high state while the switch SPT_SW is maintained in a turned-on state.

At time t2 at which the falling transition starts, the enable signal EN_SW may be switched to the logic-low state. As the switch SPT_SW is turned off, the supply voltage VSPT may fall from V3 to V1, and the first node voltage VN1 may fall from the ground voltage to −V2 having the same slope as (or a similar slope to) the supply voltage VSPT.

After time t3, the supply voltage VSPT may complete the falling transition to V1, and the first node voltage VN1 may complete the falling transition to −V2. When the falling transition is completed at time t3, the first node voltage VN1 may be charged to the ground voltage until time t4. Then, the enable signal EN_SW may be switched back to the logic-high state, and the first capacitor C1 may be reconnected to the ground GND. The first capacitor C1 may be charged during T_{CHG} defined as time from time t3 to time t4.

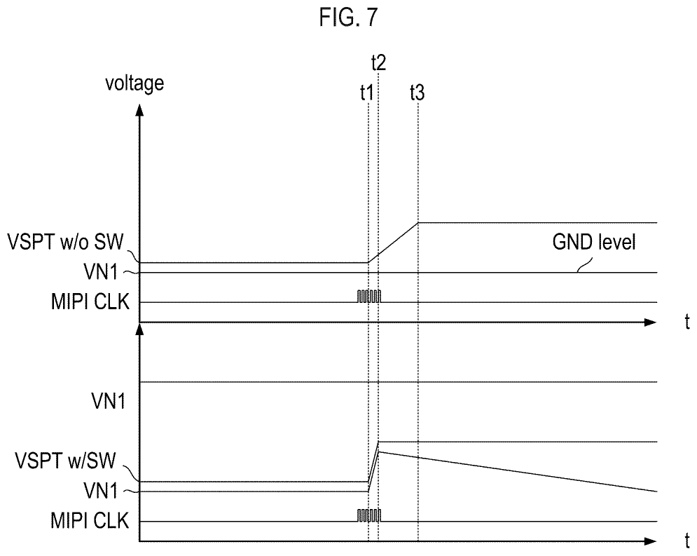

FIG. 7 is a diagram illustrating a comparison between a supply voltage of a power modulation scheme of a power modulator according to example embodiments and a supply voltage of an example power modulation scheme.

Referring to FIG. 7, an example power modulation scheme may be an average power tracking (APT) scheme for tracking average power of an RF signal. In the case of the APT scheme, a converter may supply a supply voltage VSPT through only one capacitor according to a reference voltage, without the switch SPT_SW included in the power modulator according to example embodiments.

In an example which both of the power modulation schemes work identically (or similarly) through the MIPI clock signal of FIG. 1, a transition of the supply voltage VSPT may start according to the MIPI clock signal. In this case, in both of the power modulation schemes, the transition may start at time t1. In the case of example embodiments (VSPT w/SW) in which faster transition is possible through a switch SPT_SW, the transition may be already completed at time t2, but in the case of the APT scheme (VSPT w/o SW), the transition may be completed only after reaching t3 subsequent to t2. For example, t1 to t2 may be 1 us, and t1 to t3 may be 10 us. In this case, according to example embodiments, the transition time may be decreased by about 10 times.

For example, in example embodiments (VSPT w/SW), when the switch SPT_SW is turned on and then turned off while the first node voltage VN1 is in a ground state, the first node voltage VN1 may rise with the supply voltage and be then discharged to a ground voltage, as described above in FIG. 5.

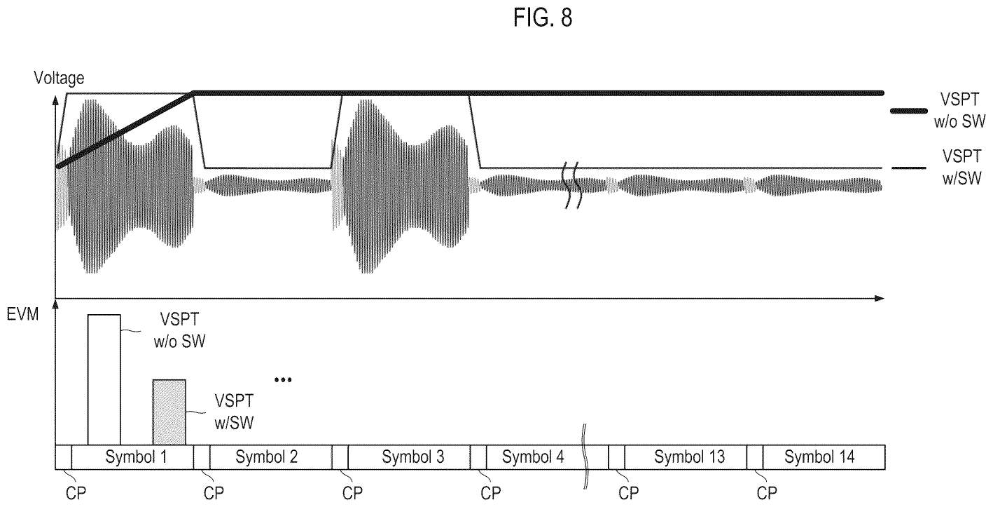

FIG. 8 is a diagram illustrating a comparison between a supply voltage of a power modulation scheme of a power modulator according to example embodiments and a supply voltage of an example power modulation scheme, for symbols.

Referring to FIG. 8, a single slot corresponding to an RF signal may include symbols Symbol 1 to Symbol 14 and a cyclic prefix (CP) corresponding to each of the symbols. For example, in a new radio (NR), a single slot of the RF signal may be 250 us with respect to a frequency of 60 kHz. In this case, a single symbol may be 16.67 us and a single CP may be 1.17 us. Durations of the slot, symbol, and CP may be defined in various ways based on the NR standard for each frequency.

In FIG. 8, an example is provided in which a high supply voltage VSPT is required (or called for or configured) at Symbol 1 and Symbol 3. In the case of the APT scheme (VSPT w/o SW), the switch SPT_SW may be not included, so that the supply voltage VSPT should be supplied through only the first capacitor Cl based on FIG. 3. Accordingly, the APT scheme may have a larger amount of transition time (for example, about 10 us), compared with example embodiments (VSPT w/SW). Therefore, even when a transition of the supply voltage VSPT is required (or called for or configured) for a specific symbol, the APT scheme should be applied only in units of slots due to a relatively large amount of transition time thereof. As illustrated in the figure, the APT scheme may be applied from Symbol 1. When the supply voltage VSPT transitions from Symbol 1, the transitioned voltage should be maintained throughout the entire slot as illustrated in the figure, so that unnecessary (or excessive) power consumption may occur in the remaining symbols except Symbols 1 and 3. Additionally, EVM performance of the APT scheme applied from Symbol 1 may be degraded. When a high voltage is required (or called for or configured) for Symbol 1, an existing APT scheme may improperly supply an optimal (or called for or configured) voltage to Symbol 1 due to slower transition time, resulting in EVM degradation. However, in example embodiments, an optimal (or improved) voltage may be supplied to Symbol 1 due to faster transition time of the supply voltage VSPT, so that EVM degradation may be reduced.

In example embodiments, the first capacitor C1 may be floated based on FIG. 3, resulting in shorter transition time (for example, about 1 us) than (as compared to) that of the APT scheme. Accordingly, the supply voltage VSPT may transition in units of symbols. In example embodiments, the supply voltage VSPT may rise for Symbol 1 and fall when a duration of Symbol 1 ends. In addition, the supply voltage VSPT may transition only for Symbols 1 and 3, so that unnecessary (or excessive) power consumption may be prevented (or reduced).

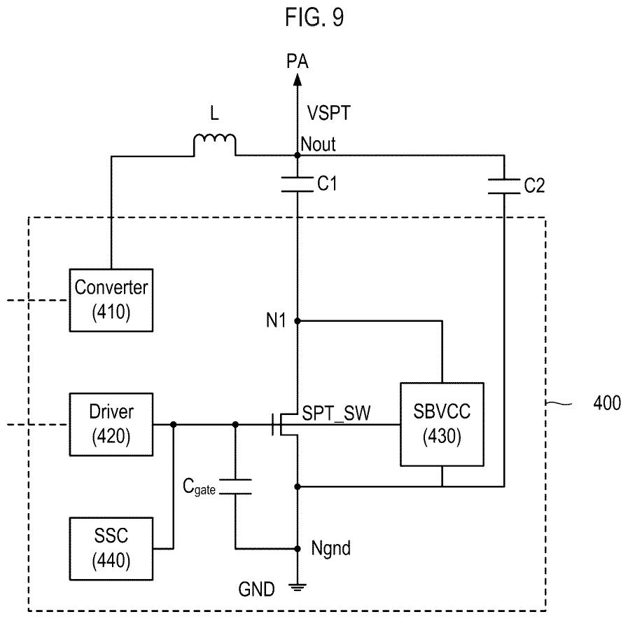

FIG. 9 is a diagram illustrating a power modulator according to example embodiments.

Referring to FIG. 9, a power modulator 400 includes a converter 410, a switch SPT_SW, a driver 420, and/or a switch body voltage control circuit 430, and may further include a gate capacitor Cgate connected to a gate terminal of the switch SPT_SW and/or a switch assist circuit 440 configured to assist a turn-on operation of the switch SPT_SW based on the gate capacitor Cgate. According to example embodiments, the power modulator 400, the converter 410, the switch SPT_SW, the driver 420 and/or the switch body voltage control circuit 430 may be the same as (or similar to) the power modulator 300, the converter 310, the switch SPT_SW, the driver 320 and/or the switch body voltage control circuit 330 discussed in connection with FIG. 3, respectively. Redundant description between FIGS. 3 and 9 may be omitted.

The gate capacitor Cgate may have one end, connected to a gate terminal of the switch SPT_SW, and the other end connected to a ground GND. Current may be supplied to the gate capacitor Cgate through the switch assist circuit 440 to store charges. For example, a charge equal to a threshold voltage of the switch SPT_SW may be stored. The threshold voltage may refer to the level of a voltage at a gate terminal at which the switch SPT_SW starts to be turned on.

The switch assist circuit 440 may be configured to charge the gate capacitor Cgate to the threshold voltage based on the completion of the supply voltage VSPT transition. For example, according to the above-described examples, the switch SPT_SW may be turned off and the supply voltage VSPT may transition. After the transition of the supply voltage VSPT transition is completed, the turn-on of the switch SPT_SW may be required (or performed) for the power modulator 400 to operate normally again. The first capacitor C1 floats during the transition, so that a voltage at one end of the switch SPT_SW (for example, a first node voltage) immediately (or promptly) after the completion of the transition may reach a level equal to a difference from the supply voltage VSPT before the transition (for example, V2 of FIG. 5 during a rising transition and −V2 of FIG. 6 during a falling transition). For example, there will be a voltage difference at the same level as (or a similar level to) a change in the supply voltage VSPT between a first node N1 and a ground node Ngnd, two terminals of the switch SPT_SW. In this case, when a voltage for turning on (for example, a driving voltage VBAT) is immediately (or promptly) applied to the gate terminal of the switch SPT_SW through the driver 420, a significant amount (for example, tens of amperes) of rush current may be momentarily generated in the switch SPT_SW due to the voltage difference between the first node N1 and the ground node Ngnd.

Therefore, the driver 420 does not turn on the switch SPT_SW immediately (or promptly) after the transition is completed. Instead, the switch assist circuit 440 may first charge the gate capacitor Cgate to the threshold voltage. When the gate capacitor Cgate is charged to the threshold voltage through the switch assist circuit 440, the voltage at the gate terminal of the switch SPT_SW may also reach the threshold voltage. When the gate terminal of the switch SPT_SW reaches a level the same as or similar to a level of the threshold voltage for turn-on, a state of the switch SPT_SW may be referred to as a slightly turned-on state for ease of description.

The gate terminal of the switch SPT_SW in the slightly turned-on state does not immediately (or promptly) reach the driving voltage VBAT, but may be maintained at a level of about (or approximately) the threshold voltage. In this case, the first node voltage does not immediately (or promptly) reach the ground voltage, but may be gradually charged or discharged to the ground voltage having a predetermined (or alternatively, given) slope. For example, one end of the switch SPT_SW connected to the other end of the first capacitor C1 may start to be charged or discharged based on the gate terminal of the switch SPT_SW reaching the threshold voltage.

For example, the first node voltage may be discharged to the ground voltage immediately (or promptly) after a rising transition, and may be charged to the ground voltage immediately (or promptly) after a falling transition.

When the first node voltage reaches the ground voltage while the switch SPT_SW is maintained in a slightly turned-on state through the switch assist circuit 440, for example, based on one end of the switch SPT_SW being charged or discharged to the ground voltage, the driver 420 may apply a turn-on voltage (for example, the driving voltage VBAT) to the gate terminal of the switch SPT_SW. In this case, a voltage difference between opposite ends of the switch SPT_SW is almost zero, so that there may be almost no rush current even when the switch SPT_SW is fully turned on.

According to the above-described examples, the power modulator 400 may stably turn on the switch SPT_SW for transition of the supply voltage VSPT without generation of rush current after the switch VSPT is turned off through the switch assist circuit 440. Accordingly, the stability of turn-on and turn-off of the switch SPT_SW for transition of the supply voltage VSPT may be secured.

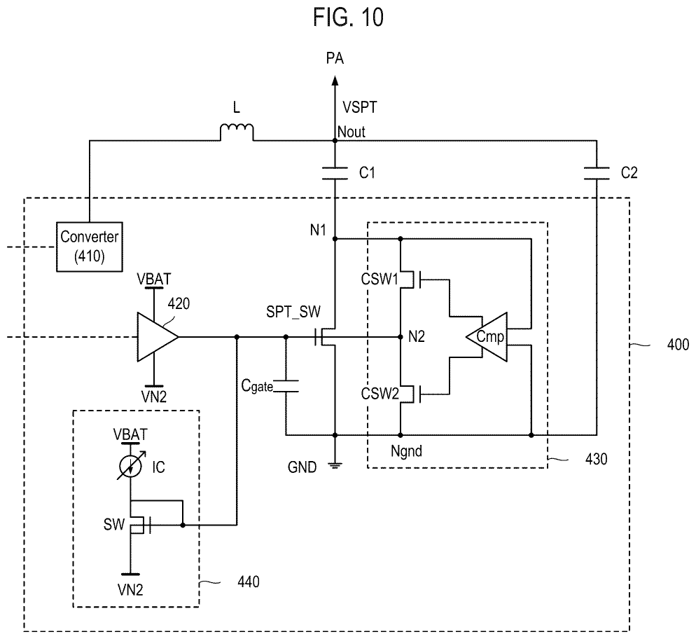

FIG. 10 is a diagram illustrating a power modulator according to the examples of FIG. 9. Hereinafter, detailed descriptions of the same content as (or a similar content to) those of the above-described examples will be omitted.

Referring to FIG. 10, the switch assist circuit 440 included in the power modulator 400 according to example embodiments may be implemented as a current mirror circuit for a switch SPT_SW. The switch assist circuit 440 may include a current source IC and a mirror switch SW.

According to example embodiments, the switch assist circuit 440 may operate after a transition of the supply voltage VSPT, started by turning off the switch SPT_SW, is terminated. The current source IC may operate depending on a driving voltage VBAT, and may provide reference current to one end of the mirror switch SW based on the driving voltage VBAT. The mirror switch SW may have one end, connected to the current source IC, and the other end applied with a second node voltage VN2 (or the other end of the mirror switch SW may be connected to ground GND). In this case, the second node voltage VN2 may have a value corresponding to the lower of a first node voltage and a ground voltage through a first control switch CSW1, a second control switch CSW2, and a comparator Cmp included in a switch body voltage control circuit 430. According to the mirror switch SW and the switch SPT_SW, mirroring current corresponding to the reference current of the current source IC may flow through the switch SPT_SW and the gate capacitor Cgate may be charged through the mirroring current. For example, the gate capacitor Cgate may be charged to a threshold voltage.

The switch SPT_SW operates in a slightly turned-on state, and the driver 420 still does not apply the driving voltage VBAT to the gate terminal of the switch SPT_SW. During the slightly turned-on state, converter 410 may provide a post-transition supply voltage VSPT to a power amplifier PA. The first node voltage VN1 may be maintained at a specific level (for example, V2 of FIG. 5 when rising, and −V2 of FIG. 6 when falling) at least until the gate capacitor Cgate is charged to the threshold voltage after transitioning to the specific level in the same direction as (or a similar direction to) the transition of the supply voltage VSPT. Then, when a voltage of the gate capacitor Cgate reaches a threshold voltage, the first node voltage VN1 may be charged or discharged to the ground voltage. When the first node voltage VN1 reaches the ground voltage, a difference in voltages at opposite ends of the switch SPT_SW (for example, a difference between the first node voltage VN1 and the ground voltage) is almost zero. Therefore, the driver 420 may apply the driving voltage VBAT to the gate terminal.

In example embodiments, the driver 420 may start to apply the driving voltage VBAT to the gate terminal of the switch SPT_SW when the first node voltage VN1 becomes equal to the ground voltage.

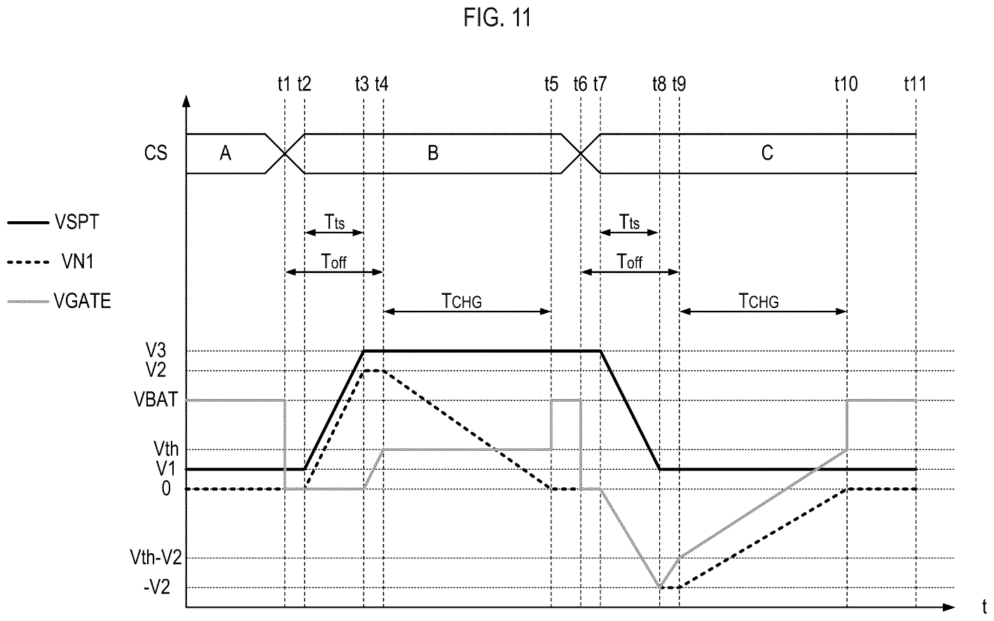

FIG. 11 is a diagram illustrating an operating waveform of a power modulator according to example embodiments.

Referring to FIG. 11, a control signal CS may be generated by a logic, not illustrated, or a modem included in a power modulator to control components and devices included in the power modulator. A single unit of the control signal CS (for example, A, B, or C) may represent a unit operation of the switch SPT_SW, and may include turn-off and turn-on operations.

When the control signal CS represents A, the switch SPT_SW is in a turned-on state, so that the power modulator may operate in normal mode. In this case, a gate voltage may represent a driving voltage VBAT, a supply voltage VSPT may represent a specific level V1, and a first node voltage may represent a ground voltage.

Then, when the control signal CS represents B, the gate voltage may decrease from the driving voltage VBAT to the ground voltage at time t1, and the switch SPT_SW may be turned off during a turn-off period T_{off}. Then, the supply voltage VSPT may rise from V1 to V3 from time t2. Since the switch SPT_SW is turned off, the first capacitor C1 may float, and the first node voltage may rise from the ground voltage, having the same slope as (or a similar slope to) the supply voltage VSPT, to a positive voltage V2. In this case, the first node voltage may rise while maintaining a difference of V1 from the supply voltage VSPT. A driver may apply a ground voltage, lower than a first node voltage, to a gate terminal of the switch SPT_SW to apply the ground voltage.

The rising transition may be performed during a transition period Tₜₛ. At time t3, the rising transition of the supply voltage VSPT may be completed.

At time t3, the gate voltage may be charged to the threshold voltage for a slight turn-on operation of the switch SPT_SW. According to the above-described examples, a charging operation may be performed on a gate capacitor connected to the gate terminal of the switch SPT_SW through the switch assist circuit. From time t3 to time t4, the gate voltage may be charged to the threshold voltage.

At time t4 at which the gate voltage is fully charged, the switch SPT_SW may perform a slight turn-on operation. Accordingly, a voltage at a first node may be discharged from V2 to a ground voltage during the charging period T_{CHG}. The supply voltage VSPT may be maintained at V3.

At time t5, when the voltage of node 1 reaches ground voltage, the switch SPT_SW may be finally fully turned on. At time t5, the driver may apply the driving voltage VBAT to the gate terminal to switch the gate voltage to the driving voltage VBAT.

From time t5 to time t6, as the switch SPT_SW is turned on, the first capacitor C1 and the second capacitor C2 may be connected to the output node Nout, and the supply voltage VSPT depending on the first capacitor C1 and the second capacitor C2 may be provided to the power amplifier PA.

From time t6, the control signal CS may represent C, and turn-off of the switch SPT_SW may be performed again. The gate voltage may decrease to the ground voltage for the turn-off. The first capacitor C1 may float again. From time t7, the supply voltage VSPT may fall from V3 to V1. Since the switch SPT_SW is turned off, the first capacitor C1 may float, and the voltage at the first node may fall from a ground voltage to a negative voltage of −V2 having the same slope as (or a similar slope to) the supply voltage VSPT. In this case, the voltage at the first node may fall while maintaining a difference of V3 from the supply voltage VSPT. The first node voltage may be applied to the gate voltage to fully turn off the switch SPT_SW. The driver may apply the first node voltage, lower than the ground voltage, to the gate terminal of the switch SPT_SW as a gate voltage to apply the first node voltage, a negative voltage. The first node voltage, a negative voltage, may be applied to the gate terminal to prevent current from flowing (or reduce an amount of current flowing) from the switch SPT_SW to the first node N1.

Similarly, the falling transition may be performed during the transition period Tts, and the falling transition of the supply voltage VSPT may be completed at time t8.

At time t8, the gate voltage may be charged to the threshold voltage for the slight turn-on operation of the switch SPT_SW. For example, the gate voltage may be charged from −V2 to Vth-V2 from time t8 to time t9.

At time t9 at which charging of the gate voltage is completed, the switch SPT_SW may perform a slight turn-on operation. Therefore, the first node voltage may be charged from −V2 to the ground voltage during the charge-discharge period T_{CHG}. The supply voltage VSPT may still be maintained at V1.

At time t10 at which the first node voltage reaches the ground voltage, the switch SPT_SW may finally fully be turned on. At time t10, the driver may apply the driving voltage VBAT to the gate terminal to switch the gate voltage to the driving voltage VBAT.

From time t10 to time t11, as the switch SPT_SW is turned on, the first capacitor C1 and the second capacitor C2 may be connected to the output node Nout, and the supply voltage VSPT depending on the first capacitor C1 and the second capacitor C2 may be provided to the power amplifier PA.

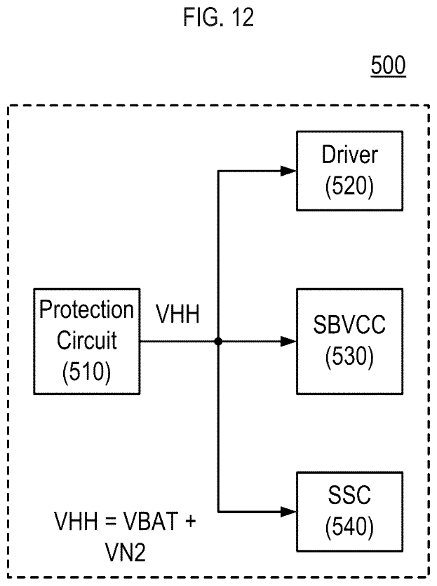

FIG. 12 is a diagram illustrating a power modulator including a protection circuit according to example embodiments.

Referring to FIG. 12, the power modulator 500 (may also be referred to herein as a power converter 500) may further include a protection circuit 510 connected to the driver 520, the switch body voltage control circuit 530, and/or the switch assist circuit 540 according to example embodiments. According to example embodiments, the power modulator 500, the driver 520, the switch body voltage control circuit 530 and/or the switch assist circuit 540 may be the same as (or similar to) the power modulator 400, the driver 420, the switch body voltage control circuit 430 and/or the switch assist circuit 440 discussed in connection with FIG. 9, respectively. Redundant description between FIGS. 9 and 12 may be omitted.

The protection circuit 510 may be configured to adjust the driving voltage VBAT of the driver 520 to a voltage that has been regulated to the sum of the driving voltage VBAT and the body voltage of the switch SPT_SW, for example, the above-mentioned second node voltage VN2. For example, in FIGS. 4 and 10, when a falling transition occurs in the supply voltage VSPT of the output node Nout, the first node voltage may also fall. For example, the first node voltage may fall to the ground voltage or the above-mentioned voltage −V2. In example embodiments, when the switch SPT_SW is to be turned off for a falling transition, the driver 520 may apply the second node voltage VN2 (for example, the first node voltage or the ground voltage) to the gate terminal of the switch SPT_SW. In this case, when the driver 520 is implemented as a transistor operating based on the driving voltage VBAT, a difference between the driving voltage VBAT and the second node voltage VN2 may momentarily occur in the driver 520. Such a reliability issue may cause damage to the driver 520.

In addition, when there are devices (for example, the comparator Cmp and/or the mirror switch SPT_SW of FIG. 10) operating based on the driving voltage VBAT and the second node voltage VN2 not only in the driver 520 but also in the switch body voltage control circuit 530 and/or the switch assist circuit 540, all of the devices are likely to be damaged due to the difference between the driving voltage VBAT and the second node voltage VN2.

Accordingly, the protection circuit 510 may be configured to adjust the driving voltage VBAT (or an operating voltage) of the driver 520, the switch body voltage control circuit 530, and/or the switch assist circuit 540 to a voltage that has been regulated to the sum of the driving voltage VBAT and the body voltage of the switch SPT_SW, for example, the second node voltage VN2. For example, the regulated voltage VHH may be defined as the sum of the driving voltage VBAT and the second node voltage VN2. As a result, as the driving voltage VBAT of the driver 520, the switch body voltage control circuit 530, and/or the switch assist circuit 540 is adjusted to the regulated voltage VHH through the protection circuit 510, the driver 520, the switch body voltage control circuit 530, and/or the switch assist circuit 540 may operate at the regulated voltage VHH. In that case, the voltage difference between the regulated voltage VHH, which is an operating voltage of the driver 520, the switch body voltage control circuit 530, and/or the switch assist circuit 540, and the second node voltage VN2 may be at most the same as (or similar to) the original driving voltage VBAT.

In example embodiments, the protection circuit 510 may be deactivated (for example, not operating) when the supply voltage VSPT rises, and may be activated (for example, be operating) when the supply voltage VSPT falls. For example, the protection circuit 510 may operate based on the supply voltage VSPT falling. For example, the protection circuit 510 may not operate when the second node voltage VN2 is the ground voltage, because it is determined as (e.g., corresponds to) a rising transition. For example, the protection circuit 510 may operate when the second node voltage VN2 is the first node voltage, because it is determined as (e.g., corresponds to) a falling transition.

According to the above-described examples, the power converter 500 may prevent or reduce damage to components and devices included in the power converter 500 during a falling transition through the protection circuit 510. In addition, the protection circuit 510 does not operate during a rising transition rather than a falling transition, thereby conserving current consumption.

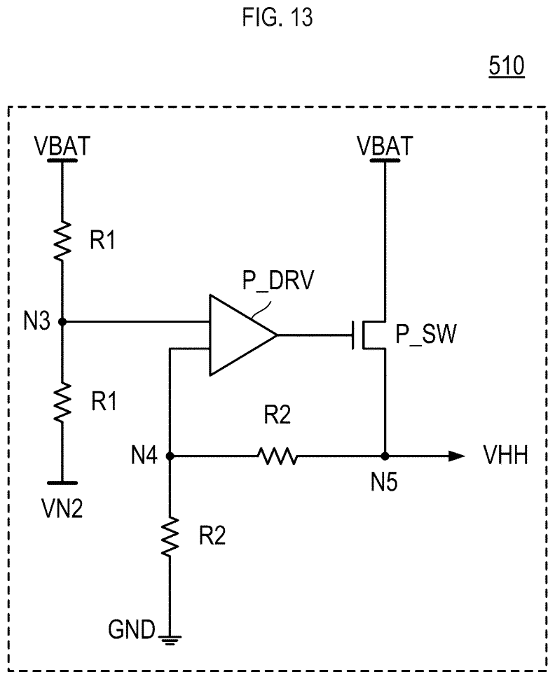

FIG. 13 is a circuit diagram of the protection circuit of FIG. 12 according to example embodiments.

Referring to FIG. 13, a protection circuit 510 may include a protection driver P_DRV and a protection switch P_SW.

A third node N3 may be connected to a portion of an input terminal of the protection driver P_DRV, and two first resistors R1 for voltage division may be connected to the third node N3. Current generated by a driving voltage VBAT may flow to a third node N3 through a portion of the first resistor R1, and current generated by a second node voltage VN2 may flow to the third node N3 through a portion of the first resistor R1. According to the voltage division, the third node N3 may be applied with a voltage of (VBAT+VN2)/2 through the two first resistors R1 having the same size (or similar sizes).

Accordingly, the remaining portion of the input terminal of the protection driver P_DRV, connected to a fourth node N4, may also be supplied with a voltage of (VBAT+VN2)/2. Two second resistors R2 may be connected to a fourth node N4. A portion of a second resistor R2 may be connected to the fourth node N4 and a ground GND, and a portion of the second resistor R2 may be connected to a fifth node N5 connected to the protection switch P_SW.

The protection switch P_SW may have one end, applied with a driving voltage VBAT, and the other end connected to the fifth node N5. In addition, the gate terminal of the protection switch P_SW may be connected to the protection driver P_DRV. Accordingly, the protection switch P_SW may be turned on or off depending on the protection driver P_DRV.

In example embodiments, a regulated voltage VHH may be applied to the fifth node N5 when a supply voltage VSPT falls, for example, when a second node voltage VN2 is a first node voltage. For example, when a voltage of (VBAT+VN2)/2 is applied to the fourth node N4, a voltage of 2*(VBAT+VN2)/2, for example, VBAT+VN2, may be applied to the fifth node N5 through two second resistors R2 having the same size (or similar sizes). Accordingly, the regulated voltage VHH may have the sum of the driving voltage (VBAT) and the voltage of the second node N2 (VN2).

The voltage at the fifth node N5, for example, the regulated voltage VHH, may be applied as a driving voltage VBAT of the driver 520, the switch body voltage control circuit 530, and/or the switch assist circuit 540, as illustrated in FIG. 12. Therefore, the power converter 500 may prevent (or reduce) breakage of the components and devices, included in the power converter 500, at the time of falling transition through protection circuit 510. In addition, even when the first node N1 according to the above-described examples turns to a negative voltage, turn-off, charging of the first node N1, and a stable operation of the driver 520 may be performed due to the switch body voltage control circuit 530 and the protection circuit 510.

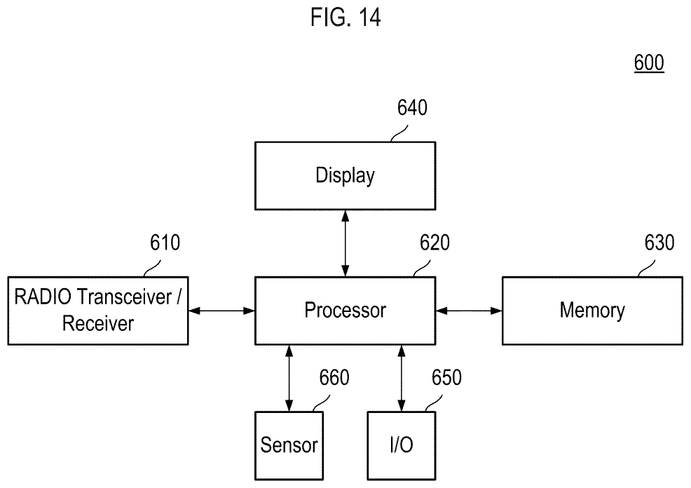

FIG. 14 is a diagram illustrating an Internet of Things (IoT) device to which a wireless communication device according to example embodiments is applied.

Referring to FIG. 14, the term “IoT” may refer to a network between things using wired/wireless communication. An IoT device may include an accessible wired or wireless interface, and may include devices that communicate with at least one other device via a wired or wireless interface to transmit or receive data. The accessible wired or wireless interface may include a wired local area network (LAN), a wireless local area network (WLAN) such as Wi-Fi, a wireless personal area network (WPAN) such as Bluetooth, or a wireless universal serial bus (USB), Zigbee, near field communication (NFC), radio frequency identification (RFID), power line communication (PLC), and/or a modem communication interface that may be connected to a mobile cellular network such as 3G, 4G, and/or long-term evolution (LTE). The Bluetooth interface may support Bluetooth low energy (BLE).

In detail, an IoT device 600 may include a communication interface 610 (RADIO transceiver/receiver) for communicating with the outside. The communication interface 610 may be, for example, a MODEM communication interface that is accessible to a wireless local area network such as a LAN, Bluetooth, Wi-Fi or Zeebee, PLC, or a mobile communication network such as 3G, LTE, 4G, or 5G. The communication interface 610 may include a transceiver and/or a receiver. The IoT device 600 may transmit and/or receive information from an access point or a gateway through the transceiver and/or the receiver. Also, the IoT device 600 may communicate with a user device or any other IoT device to transmit and/or receive control information or data of the IoT device 600.

At least one of the wireless communication devices 100 and 200 described with reference to FIGS. 1 and 2 may be implemented in the communication interface 610, and thus, at least one of the power modulators 300 to 500 described with reference to FIGS. 3 to 13 may be implemented in a transmitter of the communication interface 610.

The IoT device 600 may further include a processor or application processor (AP) 620 performing a calculation. For internal power supply, the IoT device 600 may further include an embedded battery or a power supply unit supplied with power from the outside. Also, the IoT device 600 may include a display 640 for displaying an internal state or data. The user may control the IoT device 600 through a user interface (UI) of the display 640 in the IoT device 600. The IoT device 600 may transmit an internal state and/or data to the outside through the transmitter and may receive a control instruction and/or data to the outside through the receiver.

A memory 630 may store a control instruction code controlling the IoT device 600, control data, or user data. The memory 630 may include at least one of a volatile memory or a nonvolatile memory. The nonvolatile memory includes at least one of various memories such as a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), and/or a ferroelectric RAM (FRAM). The volatile memory may include at least one of various memories such as a static RAM (SRAM), a dynamic RAM (DRAM), and/or a synchronous DRAM (SDRAM).

The IoT device 600 may further include a storage device. The storage device may include at least one of nonvolatile media such as a hard disk drive (HDD), a solid state drive (SSD), an embedded multimedia card (eMMC), and/or a universal flash storage (UFS). The storage device may store user information provided through an input/output unit (I/O) 650 and/or a plurality of pieces of sensing information collected through a sensor 660.

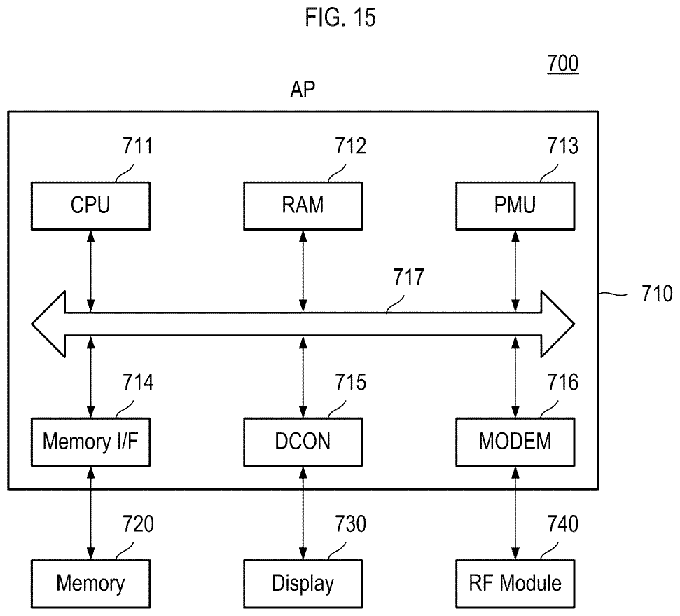

FIG. 15 is a diagram illustrating a mobile terminal to which a wireless communication device according to example embodiments is applied.

Referring to FIG. 15, a mobile terminal 700 may include an application processor (hereinafter referred to as an “AP”) 710, a memory 720, a display 730, and/or an RF module 740. The mobile terminal 700 may further include various components such as a lens, an audio module, etc.

The AP 710 may be implemented as a system-on-chip (SoC) and may include a central processing unit (CPU) 711, a RAM 712, a power management unit (PMU) 713, a memory interface (I/F) 714, a display controller (DCON) 715, a MODEM 716, and/or a system bus 717. In addition, the AP 710 may further include various intellectual properties (IPs). The AP 710 may be integrated with a function of a MODEM chip therein, which is referred to as a “ModAP.”

The CPU 711 may control the overall operation of the AP 710 and the mobile terminal 700. The CPU 711 may control an operation of each component of the AP 710. Also, the CPU 711 may be implemented as a multi-core. The multi-core may be a single computing component including two or more independent cores.

The RAM 712 may temporarily store programs, data, or instructions. For example, the programs and/or data stored in the memory 720 may be temporarily stored in the RAM 712 under control of the CPU 711 or depending on a booting code. The RAM 712 may be implemented as a DRAM or an SRAM.

The PMU 713 may manage power of each component of the AP 710. The PMU 713 may also determine an operating situation of each component of the AP 710 and may control an operation thereof.

The memory interface 714 may control the overall operation of the memory 720 and may control data exchange of the memory 720 with each component of the AP 710. Depending on a request of the CPU 711, the memory interface 714 may write data in the memory 720 or may read data from the memory 720.

The display controller 715 may transmit image data to be displayed on the display 730 to the display 730. The display 730 may be implemented as a flat panel display, such as a liquid crystal display (LCD) or an organic light emitting diode (OLED) display, or a flexible display.

For wireless communication, the modem 716 may modulate data to be transmitted so as to be appropriate for a wireless environment and may recover received data. The modem 716 may perform digital communication with the RF module 740.

For reference, the modems 110 and 210 described with reference to FIGS. 1 and 2 may be implemented in the modem 716.

The RF module 740 may convert a high-frequency signal, received through an antenna, into a low-frequency signal and may transmit the converted low-frequency signal to the modem 716. Also, the RF module 740 may convert a lower-frequency signal, received from the modem 716, into a higher-frequency signal and may transmit the converted higher-frequency signal to the outside of the mobile terminal 700 through the antenna. Also, the RF module 740 may amplify or filter a signal.

For reference, the RFIC 120, the power amplifier PA, the duplexer 130, and the antenna ANT described with reference to FIGS. 1 and 2 may be implemented in the RF module 740. The power modulators 300 to 500 described with reference to FIGS. 3 to 13 may also be implemented in the RF module 740.

For this reason, in the mobile terminal 700, broadband communication may be performed while reducing power consumption for communication.

As set forth above, according to example embodiments, a supply modulator and a wireless communication device including the same may be provided.

Wireless communication devices use power amplifiers to amplify communication signals to be transmitted. The efficiency of the power amplifiers decreases when, for example, the communication signals have a higher peak-to-average power ratio (PAPR) and/or a higher bandwidth. Such decreases in efficiency are particularly significant when a power supply of the wireless communication devices is limited (e.g., supplied through a battery). Existing devices and methods attempt to improve the efficiency of the power amplifiers using average power tracking (APT) or envelope tracking (ET) techniques. However, the existing devices and methods are unable to apply these techniques to individual symbols of the communication signals because a transition time of a supply voltage to the power amplifiers is excessively long. Accordingly, the existing devices and methods apply the techniques to entire slots of symbols resulting in excessive resource consumption (e.g., power consumption), excessive noise and/or deteriorating error vector magnitude (EVM) characteristics.

However, according to example embodiments improved devices and methods are provided for providing a supply voltage to a power amplifier. For example, the improved devices and methods may use a switch to float a larger of two load capacitors when the switch is turned off. By floating the larger capacitor, a transition time of the supply voltage to the power amplifier may be reduced enabling the supply voltage to be modulated according to individual symbols of a communication signal. Accordingly, the improved devices and methods overcome the deficiencies of the existing devices and methods to at least improve resource consumption (e.g., power consumption), reduce noise and/or improve EVM characteristics.

According to example embodiments, operations described herein as being performed by the wireless communication device 100, the modem 110, the RFIC 120, the duplexer 130, the power modulator 140, the power amplifier PA, the digital processing circuit 111 (the e.g., average power signal generation operation, the envelope extraction operation, the digital envelope signal generation operation, the crest factor reduction (CFR) 211, the shaping function (SF) 212, the digital pre-distortion (DPD) 213 and/or the delay correction operations 214 and/or 215), the DAC 112, the ADC 113, the MIPI, the transmit circuit TXC, the receive circuit RXC, the local oscillator LO, the first analog baseband filter ABF1, the first mixer MX1, the driver amplifier 121, the receive circuit RXC, the second analog baseband filter ABF2, the second mixer MX2, the low-noise amplifier (LNA) 122, the DAC1, the power modulator 300, the converter 310, the driver 320, the switch body voltage control circuit 330, the comparator Cmp, the power modulator 400, the converter 410, the driver 420, the switch body voltage control circuit 430, the switch assist circuit 440, the logic of the power modulator 400, the power modulator 500, the protection circuit 510, the driver 520, the switch body voltage control circuit 530, the switch assist circuit 540, the IoT device 600, the communication interface 610, the AP 620, the I/O 650, the sensor 660, the mobile terminal 700, the AP 710, the RF module 740, the CPU 711, the PMU 713, the memory interface (I/F) 714, the DCON 715 and/or the MODEM 716 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with example embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the memory of the modem 110, the memory 630, the memory 720, the RAM 712, etc.). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Although terms of “first” or “second” may be used to explain various components, the components are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples. As used herein the term “and/or” includes any and all combinations of one or more of the associated listed items.

While example embodiments have been shown and described above, it will be apparent to those skilled in the art that modifications and variations could be made without departing from the scope of the inventive concepts as defined by the appended claims.

What is claimed is:

1. A power modulator configured to provide a supply voltage of a power amplifier, the power modulator comprising:
a converter configured to output the supply voltage to the power amplifier;
a switch connected to a first capacitor and a second capacitor, a first end of the first capacitor being connected to the converter, a second end of the first capacitor being connected to the switch, a first end of the second capacitor being connected to the converter, a second end of the second capacity being connected to a ground and the switch, and a capacitance of the second capacitor being less than a capacitance of the first capacitor; and
a driver connected to the switch, the driver being configured to turn off the switch based on an occurrence of a transition of the supply voltage.

2. The power modulator of claim 1, further comprising:
a switch body voltage control circuit connected to the switch, the switch body voltage control circuit being configured to adjust a body voltage of the switch to a lower voltage among a voltage at the second end of the first capacitor and a ground voltage at the ground.

3. The power modulator of claim 2, wherein the switch body voltage control circuit comprises:
a first control switch, a first end of the first control switch being connected to the second end of the first capacitor, and a second end of the first control switch being connected to a body of the switch;
a second control switch, a first end of the second control switch being connected to the ground, and a second end of the second control switch being connected to the body of the switch; and
a comparator configured to
compare the voltage at the second end of the first capacitor and the ground voltage to obtain a comparison result, and
control the first control switch and the second control switch based on the comparison result.

4. The power modulator of claim 3, wherein the comparator is configured to:
turn off the first control switch and turn on the second control switch based on the voltage at the second end of the first capacitor being higher than the ground voltage; and
turn on the first control switch and turn off the second control switch based on the voltage the second end of the first capacitor being lower than the ground voltage.

5. The power modulator of claim 1, wherein the driver is configured to:
apply a ground voltage to a gate terminal of the switch based on a rising transition of the supply voltage; and
apply a voltage at the second end of the first capacitor to the gate terminal of the switch based on a falling transition of the supply voltage.

6. The power modulator of claim 1, further comprising:
a switch assist circuit configured to charge a gate capacitor to a threshold voltage based on a transition of the supply voltage being completed, the gate capacitor being connected to a gate terminal of the switch.

7. The power modulator of claim 6, wherein
a first end of the switch is connected to the second end of the first capacitor; and
the first end of the switch starts to be charged or discharged based on the gate terminal of the switch reaching the threshold voltage.

8. The power modulator of claim 7, wherein the driver is configured to apply a turn-on voltage to the gate terminal of the switch based on one end of the switch being charged or discharged to a ground voltage.

9. The power modulator of claim 1, wherein
a first end of the switch is connected to the second end of the first capacitor; and
the first end floats based on the switch being turned off.

10. The power modulator of claim 1, further comprising:
a protection circuit configured to adjust an operating voltage of the driver to a sum of a driving voltage of the driver and a body voltage of the switch.

11. The power modulator of claim 10, wherein the protection circuit is configured to operate based on the supply voltage falling.

12. The power modulator of claim 1, wherein the converter is configured to adjust the supply voltage through the second capacitor based on the switch being turned off.

13. The power modulator of claim 3, wherein
a first end of the switch and the first end of the first control switch are connected to a first node;
the body of the switch, the second end of the first control switch, and the second end of the second control switch are connected to a second node; and
a second end of the switch and the first end of the second control switch are connected to a ground node.

14. A wireless communication device comprising:
a power amplifier configured to amplify a radio-frequency (RF) signal;
a power modulator configured to provide a supply voltage of the power amplifier;
a first capacitor connected to the power amplifier and the power modulator; and
a second capacitor connected to the power amplifier and the power modulator,
wherein the power modulator comprises:
a converter configured to output the supply voltage to the power amplifier,
a switch connected to the first capacitor and the second capacitor, a first end of the first capacitor being connected to the converter, a second end of the first capacitor being connected to the switch, a first end of the second capacity being connected to the converter, a second end of the second capacitor being connected to a ground and the switch, and a capacitance of the second capacitor being less than a capacitance of the first capacitor, and
a driver connected to the switch, and the driver being configured to turn off the switch based on an occurrence of a transition of the supply voltage.

15. The wireless communication device of claim 14, wherein the power amplifier is configured to output the RF signal having a modulated voltage for each of a plurality of symbols included in the RF signal.

16. The wireless communication device of claim 14, wherein the driver is configured to:
apply a ground voltage to a gate terminal of the switch based on a rising transition of the supply voltage; and
apply a voltage at the second end of the first capacitor to the gate terminal of the switch based on a falling transition of the supply voltage.

17. The wireless communication device of claim 14, wherein
a first end of the switch is connected to the second end of the first capacitor; and
the first end of the switch floats based on the switch being turned off.

18. A power modulator configured to provide a supply voltage of a power amplifier, the power modulator comprising:
a converter configured to output the supply voltage to the power amplifier;
a switch connected to a first capacitor and a second capacitor, a first end of the first capacity being connected to the converter, a second end of the first capacitor being connected to the switch, a first end of the second capacitor being connected to the converter, a second end of the second capacitor being connected to a ground and the switch, and a capacitance of the second capacitor being less than a capacitance of the first capacitor; and
a driver connected to a gate terminal of the switch, the driver being configured to apply a lower voltage among a first voltage or a ground voltage to the gate terminal of the switch based on an occurrence of a transition of the supply voltage, the first voltage being a voltage at the second end of the first capacitor, and the ground voltage being a voltage at the ground.

19. The power modulator of claim 18, wherein the switch is turned off based on the occurrence of the transition of the supply voltage.

20. The power modulator of claim 18, wherein the driver is configured to:
apply the ground voltage to the gate terminal of the switch based on a rising transition of the supply voltage; and
apply the voltage at the second end of the first capacitor to the gate terminal of the switch based on a falling transition of the supply voltage.
